(19) United States
(12) Patent Application Publication
(10) Pub. No.: US 2004/0239545 A1
(43) Pub. Date: Dec. 2, 2004

(54) AFE device with adjustable bandwidth filtering functions

(76) Inventors: Jui-Yuan Tsai, Tainan City (TW); Jui-Cheng Huang, Hsinchu City (TW); Chao-Cheng Lee, Jhongli City (TW); Wen-Chi Wang, Siluo Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/771,773

(22) Filed: Feb. 4, 2004

(30) Foreign Application Priority Data
Apr. 17, 2003 (TW) 092108990

(51) Int. Cl. H03M 1/12

(52) U.S. Cl. 341/155

(57) ABSTRACT

An AFE device with adjustable bandwidth filtering functions includes an input buffer and an ADC, and the adjustable bandwidth filtering functions may be integrated in the ADC or the input buffer. When they are integrated in the ADC, a capacitor and a switch module in the ADC may implement the functions, wherein the capacitor originally samples and holds analog signals. The switch module includes a plurality of transistor switches connected in parallel, and one (or multiple ones connected in parallel) of the transistor switches may be selected, according to a selection code, as an equivalent resistor to be serially connected to the capacitor to form a filter circuit. The selection code may be a one-of-N code or a thermometer code.

This application claims the benefit of Taiwan application Ser. No. 92108990, filed Apr. 17, 2003.

### BACKGROUND OF THE INVENTION

1. Field of the Invention

The invention relates to an AFE (analog front end) device with filtering functions, and more particularly to an AFE device with adjustable bandwidth filtering functions.

2. Description of the Related Art

The cathode ray tube (CRT) display technology is always the mainstream of display for a long time, and its associated technology is well developed after several tens of years of improvements. Recently, the display technology has been greatly modified owing to the trend of digitalization. Thus, the LCD monitor tends to replace the CRT monitor.

In the applications of the personal computers, because many display cards (VGA cards) can only output analog image signals, the LCD has to convert the received analog signals into digital signals for display. Therefore, the LCD controller of the monitor must have an analog front end (AFE) device and a scalar for performing operations of signal conversion and scaling, wherein the AFE device is for converting analog image signals into digital image signals, while the scalar is for computing the digital image signals so as to obtain images with various resolutions. With the development of the manufacturing technology and the increasement of the degree of integration of devices, the current trend is to integrate the AFE device, the scalar and some peripheral circuits on the same chip, which is referred as a LCD control chip.

As shown in FIG. 1, a tipycal AFE device composed of three selts of circuits with the same configuration is employed to convert red (R), green (G) and blue (B) analog signals RA, GA, and BA into red, green, and blue digital signals RD, GD and BD. In detail, each set of circuit is composed of a damper 110, an input buffer IB, and an ADC (analog-to-digital converter) 130. The damper 110 may hold the analog image signals at a predetermined level. Then, the input buffer IB buffers the signals and then feeds them to the ADC 130 for conversion. In addition, the AFE device further includes a clock generator 150, a bandgap voltage reference circuit 170, and the like. The clock generator 150 may provide clock signals CLK required by the ADC 130, and adjustment signals ADJ generated by the bandgap voltage reference circuit 170 is employed to adjust the gain and offset voltage of the input buffer IB.

The input buffer IB may be implemented by a source follower, as shown in FIG. 2. The input buffer IB is composed of an impedance Rs, a current source lo and a transistor Mp. The RGB analog signals fed from the damper 110 may be equivalent to an input voltage Vin. A capacitor C will sample and hold the RGB analog signals when they are fed to the ADC 130. When the switches SW1 and SW2 are turned on, the capacitor C samples the analog signals. After the sampling process is finished, the switches SW1 and SW2 are turned off, and the signals may be held and serve as signal sources for the post-stage circuit. The switches SW1 and SW2 may be transistor switches, for example.

In the practical application, because of the trace layout or other environmental factors of the printed circuit board (PCB), or the noise from the original signal source, high-frequency noises often exist in the RGB analog signals and thus cause ripples or distortion phenomena on the LCD monitor. One way for solving this noise problem is to design an additional filter circuit in the original circuit. In practice, the bandwidth of the filter circuit is designed to be about more than three times of the frequency of the clock signal CLK. That is, if the frequency of the clock signal CLK is 140 MHz, the bandwidth of the filter circuit is about 500 MHz. Because the display modes of the LCD control chip have to cover the minimum frequency to the maximum frequency, the filter circuit in the chip must have an adjustable bandwidth (e.g., the bandwidth may be chosen among 75, 150, 300, and 500 MHz) so as to have the practical value. In the chip, however, it is quite difficult to implement the active filter circuit having a large rang bandwidth and higher linearity than that of the post-stage ADC.

### SUMMARY OF THE INVENTION

It is therefore an object of the invention to provide an AFE device with adjustable bandwidth filtering functions without complex filter circuit for filtering out high-frequency noises under various display modes.

The invention achieves the above-identified object by providing an AFE device with easy adjustable bandwidth filtering functions. The device includes an input buffer and an ADC, and the adjustable bandwidth filtering functions may be integrated in the ADC or the input buffer. When they are integrated in the ADC, a capacitor and a switch module in the ADC may implement the functions, wherein the capacitor originally samples and holds analog signals. The switch module includes a plurality of transistor switches connected in parallel, and one (or multiple ones connected in parallel) of the transistor switches may be selected, according to a selection code, as an equivalent resistor to be serially connected to the capacitor to form a filter circuit. The selection code may be a one-of-N code or a thermometer code. When they are integrated in the input buffer, a plurality of transistors may be connected in parallel to form a transistor module, wherein one of the transistors or multiple ones of the transistors connected in parallel may be selected as a filter circuit according to a selection code; or multiple current sources may be connected in parallel to form a current source module, wherein one of the current sources or multiple ones of the current sources connected in parallel may be selected, according to a selection code, to adjust the total output current and thus achieve the object of adjusting the filtering bandwidth.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 shows a typical AFE device.

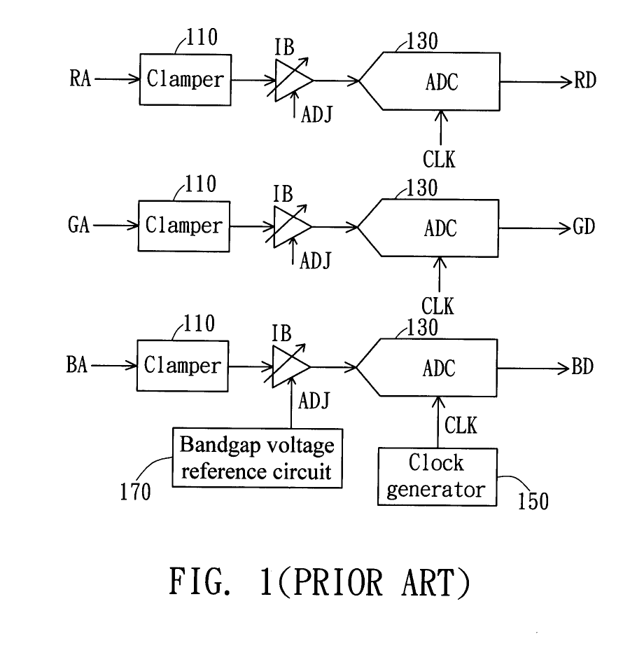

FIG. 2 shows an input buffer implemented by a source follower.

FIG. 3 shows an ADC according to a first embodiment of the invention.

FIG. 4 shows a small signal equivalent circuit of the transistor of the input buffer.

FIG. 5 shows an input buffer according to a second embodiment of the invention.

FIG. 6 shows another input buffer according to the second embodiment of the invention.

### DETAILED DESCRIPTION OF THE INVENTION

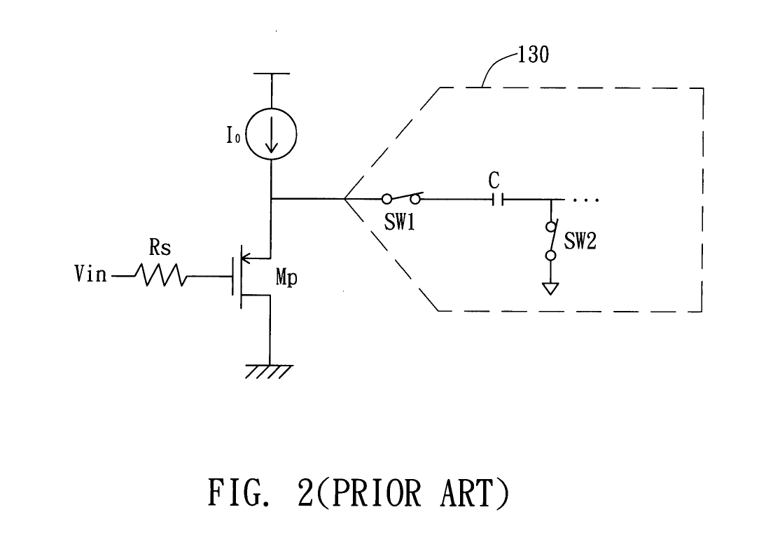

The concept of the invention is to integrate a filter circuit in an original circuit (e.g., an ADC or an input buffer) of an AFE device so as to prevent the signal property from being influenced because the original circuit architecture is not modified too significantly. As clearly illustrated in FIG. 2, the capacitor C may sample and hold the analog signals. That is, the signals are sampled when the switches SW1 and SW2 are turned on, and are held when the switches are turned off. Consequently, the capacitor C and the switches SW1 and SW2 may be regarded as a sample and hold circuit for analog signals. It is to be noted that the switches SW1 and SW2 are often implemented by transistors (PMOS or NMOS). Because the transistors themselves have inherent resistances, the switches SW1 and SW2 may be equivalent to resistors R1 and R2, respectively. When the switches SW1 and SW2 are turned on, it may be regarded as that the resistor R1, the capacitor C, and the resistor R2 are connected in series. Thus, the sample and hold circuit in this case also has filtering effects, and may have filtering functions for filtering some specific bandwidth as long as the structure of the switches SW1 and SW2 or the capacitor C is changed.

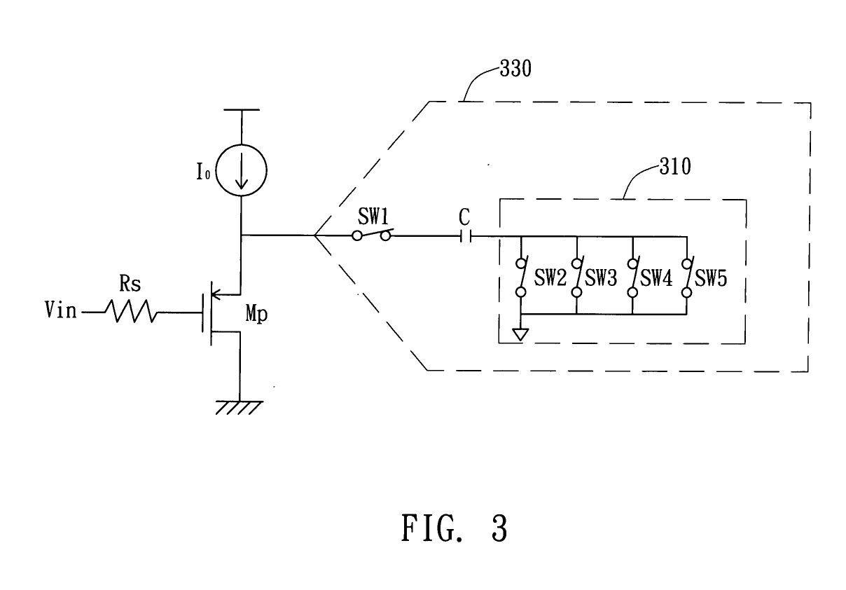

In order to adjust the bandwidth of the filter circuit according to the actual demands, the first embodiment utilizes multiple transistor switches connected in parallel to form a switch module, which may select specific one or more transistor switches to operate according to different bandwidth settings so as to achieve the object of filtering out multiple high-frequency signals in conjunction with the capacitor C. FIG. 3 shows an ADC 330 according to a first embodiment of the invention. The adjustable bandwidth filtering functions are integrated in the sample and hold circuit. The switch module 310 includes four transistor switches SW2, SW3, SW4 and SW5, which may produce the filtering effects for filtering four different bandwidths (e.g., 75, 150, 300, 500 MHz) in conjunction with the capacitor C. When the switch module 310 is designed, it is possible to determine which one of the transistor switches or which transistor switches are to be serially connected to the capacitor C so as to implement the above-mentioned four adjustable bandwidths according to a selection code, which may be the one-of-N code, the thermometer code, or the like. According to the one-of-N code, one of the four transistor switches is selected to be serially connected to the capacitor C at each time. According to the thermometer code, a desired resistance value may be formed by selecting various combinations of the four transistor switches, and the number of the selected transistor switch/switches may be one or more than one.

Illustration will be made by taking the bandwidth settings of 75, 150, 300, and 500 MHz as an example. If the switch module 310 is configured to select the transistor switch according to the one-of-N code, the length-to-width ratios of the transistor switches SW2, SW3, SW4 and SW5 may be set to 1:2:4:6.6 (i.e., W/L, 2W/L, 4W/L, 6.6W/L). In this case, only the transistor switch SW2 is selected when the bandwidth is 75 MHz; only the transistor switch SW3 is selected when the bandwidth is 150 MHz; only the transistor switch SW4 is selected when the bandwidth is 300 MHz; and only the transistor switch SW5 is selected when the bandwidth is 500 MHz, and the desired bandwidth may be set accordingly. If the switch module 310 is configured to select the transistor switch/switches according to the thermometer code, the length-to-width ratios of the transistor switches SW2, SW3, SW4 and SW5 may be set to 1:1:2:2.6 (i.e., W/L, W/L, 2W/L, 2.6W/L). In this case, only the transistor switch SW2 is selected when the bandwidth is 75 MHz; only the transistor switches SW2 and SW3 are selected when the bandwidth is 150 MHz; only the transistor switches SW2, SW3, and SW4 are selected when the bandwidth is 300 MHz; and the transistor switches SW2, SW3, SW4 and SW5 are selected when the bandwidth is 500 MHz. Therefore, the filtering effects of filtering different bandwidths may be obtained by selecting various combinations of the four transistor switches.

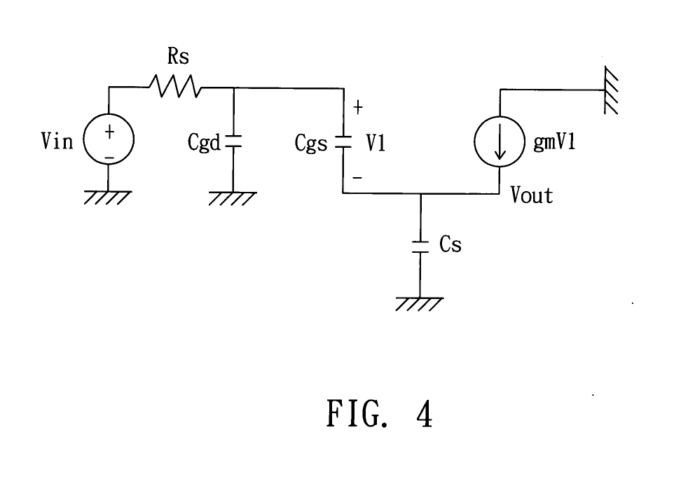

Thus, the filtering bandwidth may be adjusted by adjusting the transistor switches of the ADC. Of course, similar effects may be obtained by adjusting the input buffer. FIG. 4 shows a small signal equivalent circuit of the transistor Mp of the input buffer IB. As clearly shown in FIG. 4, equivalent capacitors do exist between any two of the source, drain, and gate of the transistor Mp. Therefore, if the structure of the transistor is adjusted, the object of adjusting the bandwidth also may be achieved.

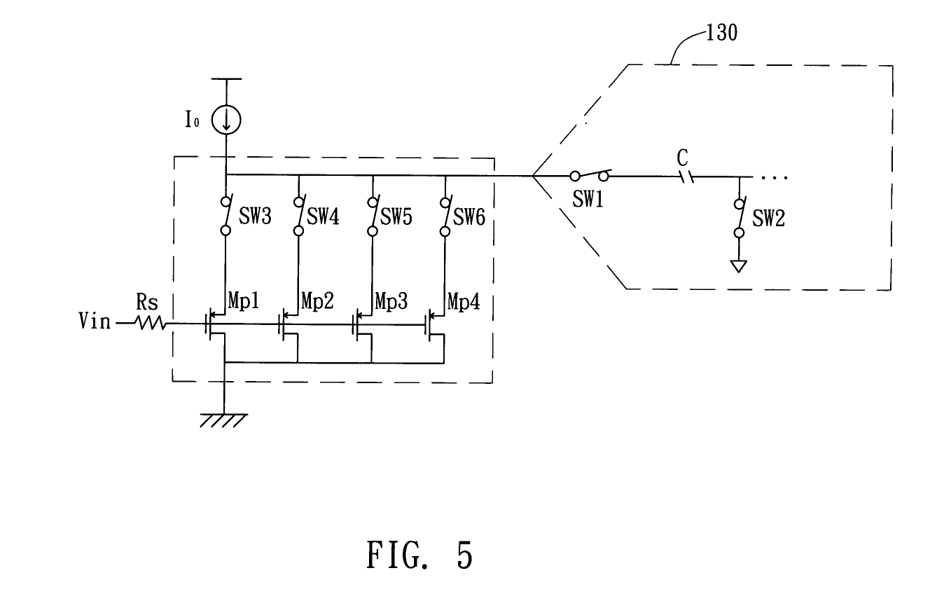

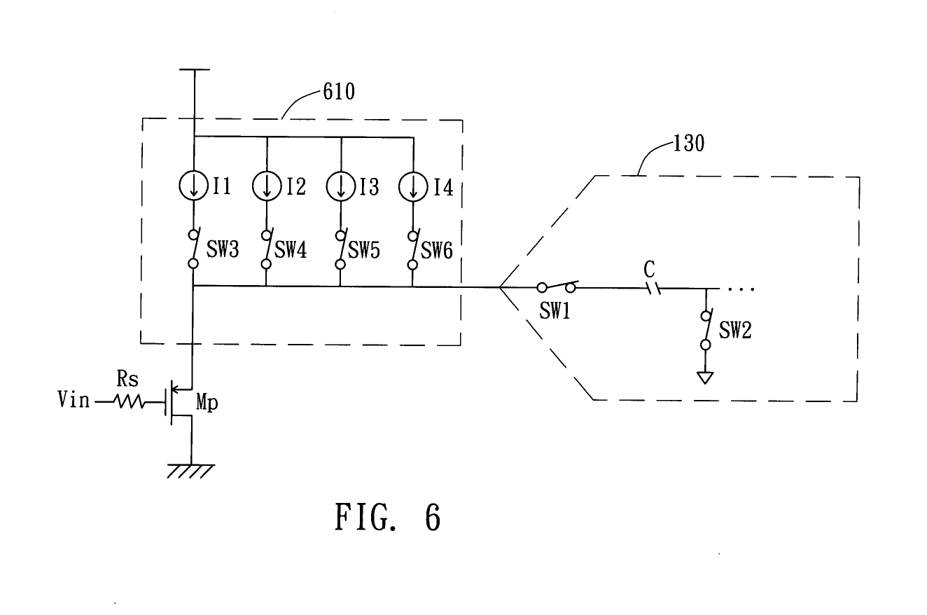

FIG. 5 shows an input buffer according to a second embodiment of the invention, wherein the input buffer is integrated with the adjustable bandwidth filtering functions. In practice, four transistors Mp1, Mp2, Mp3 and Mp4 constitute a transistor module 510, and the ON states of the switches SW3, SW4, SW5 and SW6 are determined according to the selection code (e.g., the one-of-N code, the thermometer code, or the like). One or multiple ones of the transistors are selected to be connected in parallel to the current source lo to form a source follower, which implement the object of the adjustable bandwidth. Of course, similar functions may be obtained by adjusting the current source. FIG. 6 shows another input buffer according to the second embodiment of the invention. The current source module 610 may be composed of four current sources I1, I2, I3 and I4, and the ON states of the switches SW3, SW4, SW5 and SW6 are determined according to the selection code. One or multiple ones of the current sources are selected to be connected in parallel to the transistor Mp to form a source follower. The bandwidth gets larger as the output current of the current source gets larger, and the total current value is almost in positive proportion to the bandwidth.

In the AFE device with the adjustable bandwidth filtering functions according to the embodiments of the invention, it is possible to integrate the functions in the sample and hold circuit of the ADC or the input buffer. The original circuit only has to be slightly modified, and the adjustable bandwidth filtering functions may be significantly achieved without influencing the signal quality.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An ADC (analog-to-digital converter) with adjustable bandwidth filtering functions, the ADC being disposed in an AFE (analog front end) device of a LCD controller to convert an analog signal into a digital signal, the ADC comprising:
a capacitor for sampling and holding the analog signal; and
a switch module serially connected to the capacitor, the switch module comprising a plurality of transistor switches connected in parallel, wherein the switch module selects, according to a selection code, at least one of the transistor switches as an equivalent resistor to constitute a filter circuit together with the capacitor.

2. The ADC according to claim 1, wherein the selection code is a one-of-N code, and one of the transistor switches is selected as the equivalent resistor according to the one-of-N code.

3. The ADC according to claim 1, wherein the selection code is a thermometer code, and one of the transistor switches is selected, or multiple ones of the transistor switches connected in parallel are selected as the equivalent resistor according to the thermometer code.

4. The ADC according to claim 1, further comprising a switch serially connected to the capacitor.

5. An input buffer with adjustable bandwidth filtering functions, the input buffer being disposed in an AFE (analog front end) device of a LCD controller to buffer an analog signal, the input buffer comprising:
a current source; and
a transistor module serially connected to the current source to form a source follower, the transistor module comprising a plurality of transistors connected in parallel, wherein the transistor module selects, according to a selection code, at least one of the transistors to be serially connected to the current source to form a filter circuit.

6. The input buffer according to claim 5, wherein the selection code is a one-of-N code, and one of the transistors is selected to be serially connected to the current source according to the one-of-N code.

7. The input buffer according to claim 5, wherein the selection code is a thermometer code, and one of the transistors is selected or multiple ones of the transistors are selected to be connected in parallel with each other or one another and then to be serially connected to the current source according to the thermometer code.

8. The input buffer according to claim 5, wherein the transistor module has an input terminal serially connected to an impedance.

9. The input buffer according to claim 8, wherein the impedance is equivalent to and implemented by a transistor switch.

10. An input buffer with adjustable bandwidth filtering functions, the input buffer being disposed in an AFE (analog front end) device of a LCD controller to buffer an analog signal, the input buffer comprising:
a transistor; and
a current source module serially connected to the transistor to form a source follower, the current source module comprising a plurality of current sources connected in parallel to each other or one another, wherein the current source module selects, according to a selection code, at least one of the current sources to be serially connected to the transistor to form a filter circuit.

11. The input buffer according to claim 10, wherein the selection code is a one-of-N code, and one of the current sources is selected to be serially connected to the transistor according to the one-of-N code.

12. The input buffer according to claim 10, wherein the selection code is a thermometer code, and one of the current sources is selected or multiple ones of the current sources are selected to be connected in parallel with each other or one another and then to be serially connected to the transistor according to the thermometer code.

13. The input buffer according to claim 10, wherein the transistor has an input terminal serially connected to an impedance.

14. The input buffer according to claim 13, wherein the impedance is equivalent to and implemented by a transistor switch.
